(19) United States
(12) Patent Application Publication
(10) Pub. No.: US 2026/0252260 A1
(43) Pub. Date: Aug. 27, 2026

(54) SEMICONDUCTOR DEVICES, MEMORIES, SYSTEMS AND METHOD OF DATA PROCESSING

(71) Applicant: Yangtze Memory Technologies Holding Co., Ltd., Wuhan (CN)

(72) Inventors: Chunyuan HOU, Wuhan (CN); Zongliang HUO, Wuhan (CN); Jiawei CHEN, Wuhan (CN); Mei WANG, Wuhan (CN); Wenjie MU, Wuhan (CN)

(21) Appl. No.: 19/308,635

(22) Filed: Aug. 25, 2025

(30) Foreign Application Priority Data
Dec. 23, 2024 (CN) 202411907477.8

(51) Int. Cl. G06F 3/06

(52) U.S. Cl. CPC G06F 3/0655; G06F 3/0604; G06F 3/0673

(57) ABSTRACT

A semiconductor device, a memory, a system and a method of data processing are disclosed in the present disclosure. An example semiconductor device includes a logic die and a plurality of memory dies which are stacked, the logic die comprises a plurality of data processing units each comprising a serial-parallel conversion circuit and an interface circuit. The interface circuit is configured to output the second readout data to a processor and receive first write data with a bit width of N from the processor and transmit the first write data to the serial-parallel conversion circuit. The serial-parallel conversion circuit is configured to parallelize the first write data to obtain second write data with a bit width of M and transmit the second write data to the at least one of the memory dies, wherein M and N are positive integers, and M/N is greater than or equal to 2.

### CROSS-REFERENCE TO RELATED APPLICATIONS

This application claims priority to Chinese Patent Application No. 202411907477.8, filed on Dec. 23, 2024, which is hereby incorporated by reference in its entirety.

### TECHNICAL FIELD

The present disclosure relates to the field of semiconductor technology, and in particular, to semiconductor devices, memories, systems, and methods of data processing.

### BACKGROUND

With the significant development of technologies such as big data, artificial intelligence, etc., packaged semiconductor devices are required to have higher integration and higher performance. Unlike two-dimensional structures in which semiconductor dies are arranged on one plane, various techniques involving a three-dimensional structure in which multiple semiconductor dies are vertically stacked are emerging. A high bandwidth memory (HBM) is an example of the three-dimensional structure. The high bandwidth memory can realize large-capacity and high-speed large-bandwidth to meet the requirements of artificial intelligence on memory, while continuously improving the performance of the high bandwidth memory and reducing costs is currently a challenge.

### SUMMARY

Examples of the present disclosure provide a semiconductor device, a system and a method of data processing.

According to a first aspect, an example of the present disclosure provides a semiconductor device, comprising: a logic die and a plurality of memory dies stacked on the logic die along a first direction, wherein the logic die comprises:
a plurality of data processing units, wherein each of the data processing units comprises: an interface circuit; and a serial-parallel conversion circuit coupled to the interface circuit and at least one of the memory dies,
wherein the serial-parallel conversion circuit is configured to: serialize first readout data with a bit width of M output by the at least one of the memory dies to obtain second readout data with a bit width of N;
the interface circuit is configured to: output the second readout data to a processor;
the interface circuit is further configured to: receive first write data with a bit width of N from the processor and transmit the first write data to the serial-parallel conversion circuit; and
the serial-parallel conversion circuit is further configured to: parallelize the first write data to obtain second write data with a bit width of M and transmit the second write data to the at least one of the memory dies, wherein M and N are positive integers, and M/N is greater than or equal to 2.

According to a second aspect, the present disclosure provides a memory, comprising:
a plurality of memory dies stacked along a first direction; and
a logic die stacked with the plurality of memory dies along the first direction, wherein the logic die comprises:
a serial-parallel conversion circuit coupled to at least one of the memory dies; and
an interface circuit coupled to the serial-parallel conversion circuit and a peripheral device,
wherein the serial-parallel conversion circuit is configured to: transmit data with a bit width of M at a first transmission rate to a corresponding memory die; and transmit data with a bit width of N at a second transmission rate to the interface circuit directly, wherein M and N are positive integers, and M/N is greater than or equal to 2.

According to a third aspect, an example of the present disclosure provides a system, comprising:
a semiconductor device according to any one of the first aspect of the present disclosure or a memory according to any one of the second aspect of the present disclosure; and
a processor coupled to a logic die in the semiconductor device or the memory and configured to: transmit the first write data to the logic die or read the second read data from the logic die.

According to a fourth aspect, an example of the present disclosure provides a method of data processing applied to a semiconductor device, wherein a semiconductor device comprises: a plurality of memory dies; and a logic die comprising a plurality of data processing units, wherein each of the data processing units comprises: an interface circuit; and a serial-parallel conversion circuit coupled to at least one of the memory dies and the interface circuit, wherein the method comprises:
serializing, by the serial-parallel conversion circuit, first readout data with a bit width of M output by the at least one of the memory dies to obtain second readout data with a bit width of N, and transmitting the second readout data to the interface circuit; outputting, by the interface circuit, the second readout data to a processor;
receiving, by the interface circuit, first write data with a bit width of N from the processor and transmitting the first write data to the serial-parallel conversion circuit; and parallelizing, by the serial-parallel conversion circuit, the first write data to obtain second write data with a bit width of M and transmitting the second write data to the at least one of the memory dies, wherein M and N are positive integers, and M/N is greater than or equal to 2.

In the examples of the present disclosure, by disposing the serial-parallel conversion circuit and the interface circuit on the logic die instead of the memory die, the following advantages are achieved. Firstly, the area of the memory die can be reduced. Also, since the logic die itself can be fabricated using more advanced technology, the serial-parallel conversion circuit and the interface circuit can be implemented in a smaller area, which facilitates the overall miniaturization of the semiconductor device. Secondly, after relocating the serial-parallel conversion circuit and the interface circuit from the memory die, the memory die mainly comprises a memory cell array and connection structures (for example, through silicon vias, TSV), and the manufacturing difficulty thereof is lower than that of the serial-parallel conversion circuit and the interface circuit. Thus, the manufacturing difficulty of the memory die can be reduced, and the cost of the memory die can be reduced, the layout difficulty of the memory die can also be reduced, thus the design difficulty can be reduced, which facilitates the improvement of the manufacturing yield and the reliability of the device. Thirdly, since the power consumption of the serial-parallel conversion circuit and the interface circuit is relatively high, so the serial-parallel conversion circuit and the interface circuit can be relocated to the logic die and manufactured using more advanced technology. This reduces the power consumption of the serial-parallel conversion circuit and the interface circuit, thereby reducing the overall power consumption of the semiconductor device. In addition, when the serial-parallel conversion circuit is relocated to the logic die, the channel design is more flexible. It can be understood that if the serial-parallel conversion circuit is located on the memory die, it could only receive data from a single memory die, limiting each channel to correspond to one memory die. In contrast, in this example, the serial-parallel conversion circuit is disposed on the logic die, enabling it to exchange data with one or more memory dies. In this case, the data in one channel may come from one or more memory dies, that is, the channel may correspond to one or more memory dies. The configuration of the channel is more flexible, which facilitates optimization algorithms to achieve higher memory performance.

### BRIEF DESCRIPTION OF DRAWINGS

FIG. 1 is a schematic diagram of a system according to an example of the present disclosure.

FIG. 2 is a first schematic diagram of a semiconductor device according to an example of the present disclosure.

FIG. 3 is a schematic diagram of data transmission of a data processing unit according to an example of the present disclosure.

FIG. 4 is a partial enlarged view of a logic die shown in FIG. 2.

FIG. 5 is a second schematic diagram of a semiconductor device according to an example of the present disclosure.

FIG. 6 is a schematic diagram of a memory die according to an example of the present disclosure.

FIG. 7 is a schematic diagram of a data processing unit according to an example of the present disclosure.

FIG. 8 is a schematic diagram of a channel according to an example of the present disclosure.

FIG. 9 is a schematic flowchart of a method of data processing according to an example of the present disclosure.

### DETAILED DESCRIPTION

Examples disclosed in the present disclosure will be described in more detail below with reference to the accompanying drawings. Although examples of the present disclosure are shown in the accompanying drawings, it is to be understood that the present disclosure may be implemented in various forms and should not be limited to the examples set forth herein. Rather, these examples are provided so that the present disclosure can be more thoroughly understood and the scope disclosed in the present disclosure can be fully conveyed to those skilled in the art.

In the following description, numerous details are given in order to provide a more thorough understanding of the present disclosure. However, it will be apparent to one skilled in the art that the present disclosure may be practiced without one or more of these details. In other examples, in order to avoid confusion with the present disclosure, some technical features known in the art are not described; that is, not all features of the actual example are described herein, and well-known functions and structures are not described in detail.

In the drawings, like reference numbers refer to like elements throughout.

It should be understood that spatial relation terms such as “beneath,” “below,” “lower,” “under”, “above,” “upper,” etc., may be used herein for ease of description to describe the relationship between one element or feature and other elements or features shown in the figures. It should be appreciated that in addition to the orientations shown in the figures, the spatial relation terms are also intended to comprise different orientations of the devices in use and operation. For example, if the devices in the figures are flipped, then described as “below” or “under” or “beneath” other elements or features will be oriented “on” other elements or features. Thus, the example terms “below” and “under” may comprise both upper and lower orientations. The devices may be additionally oriented (rotated 90 degrees or other orientations) and the spatial description terms used herein are interpreted accordingly.

A term used herein is for the purpose of describing a particular example only and is not to be considered as limitation of the present disclosure. As used herein, the singular forms “a”, “an” and “said/the” are intended to comprise the plural forms as well, unless the context clearly dictates otherwise. It should also be understood that, at least one of the terms “consists of” or “comprising”, when used in this description, identify the presence of at least one of stated features, integers, operations, elements or parts, but do not exclude the presence or addition of at least one of one or more other features, integers, operations, elements, parts or groups. As used herein, the term “at least one of . . . or . . . ” comprises any and all combinations of the associated listed items.

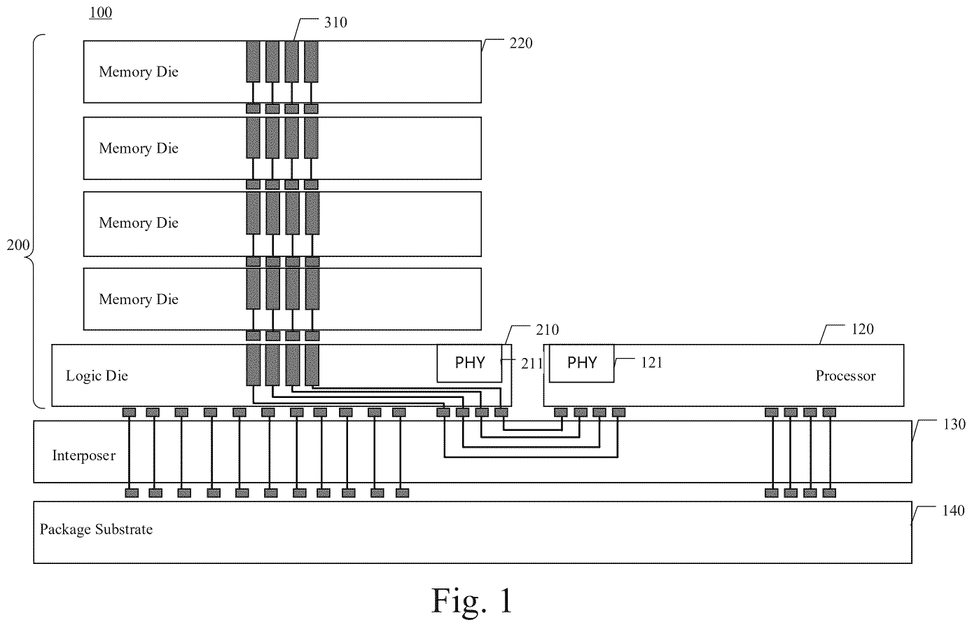

FIG. 1 is a schematic diagram of a system according to an example of the present disclosure. Referring to FIG. 1, the system 100 may comprise a memory 200, a processor 120, an interposer 130, and a package substrate 140. The memory 200 comprises a logic die 210 and a plurality of memory dies 220 stacked on the logic die 210. The memory 200 and the processor 120 may be disposed on the interposer 130, and the interposer 130 may be disposed on the package substrate 140.

Within the system 100, the processor 120 and the memory 200 may communicate with each other using various protocols. When the memory is implemented in HBM, the processor 120 and the memory 200 may communicate through a protocol related to HBM. The processor may be implemented in a form such as a central processing unit (CPU), a graphics processing unit (GPU), and a system on chip (SOC), etc. In some examples, a memory controller may be integrated in the processor 120. While in other examples, the memory controller may also be independently formed on the die in the form of a memory controller die. However, in the present disclosure, the memory controller die is also considered as a processor. The processor 120 may control the memory 200 to perform any operations related to data storage.

The processor 120 may be configured to control the memory 200 to perform operations such as data reading and data writing, etc. The processor 120 may send a command CMD and an address Add to the memory 200. The command CMD may be a signal indicating the memory 200 to write or read data by accessing a row of the memory cell array corresponding to the address Add. The address Add comprises a bank address, a row address, and a column address to be accessed in the memory cell array. In addition, a plurality of independent channels (CHs) are used for data transmission between the processor 120 and the memory 200, and each channel may configure independent command interfaces, address interfaces, and data interfaces between the processor 120 and the memory 200, and the data access among channels does not affect each other.

With continued reference to FIG. 1, the memory 200 may comprise a logic die 210 and memory dies 220 stacked on the logic die 210. The processor 120 may be coupled to the logic die 220 of the memory and communicate with the logic die 210 to control the memory 200 to perform any operations related to data access. The processor 120 may send the command CMD, the address Add, and the write data to the logic die 210, which may send the readout data to the processor 120.

The physical layer (PHY) 211 of the logic die 210 is coupled to the physical layer (PHY) 121 of the processor 120. The physical layer comprises a physical module in the interface circuit, which can perform data transmission. For example, the physical layer 211 in the logic die 210 is configured to exchange data with the physical layer 121 in the processor 120 according to a particular protocol. In addition, the physical layer 211 in the logic die 210 may also provide signals, frequencies, timing, drivers, detailed operational parameters, and functions required for the memory 200 and the processor 120 to communicate.

In some examples, as shown in FIG. 1, the physical layer 211 in the logic die 210 may be coupled to the physical layer 121 in the processor 120 through the interposer 130. For example, in the interposer 130, interconnect lines are provided between the pads of the physical layer 211 for connecting the logic die and the pads of the physical layer 211 for connecting the processor, so that data exchange occurs between the physical layer 211 of the logic die and the physical layer 121 of the processor.

Within the memory 200, a plurality of memory dies 220 are stacked on the logic die 210, and a memory cell array (not shown) and a plurality of through silicon vias (TSV) 310 are formed in the memory die 220. The plurality of memory dies 220 are coupled to the logic die 210 through the through silicon vias 310. For example, the memory die 220 may comprise a random access memory (RAM), such as a dynamic random access memory (DRAM), synchronous DRAM (SDRAM), static RAM (SRAM), double data rate SDRAM (DDR SDRAM), DDR2 SDRAM, DDR3 SDRAM, DDR4 SDRAM, DDR5 SDRAM, DDR6 SDRAM, etc.

The peripheral circuits in the memory are divided according to functions, wherein some of the peripheral circuits are disposed on a logic die, such as control logic, physical layers, etc., and some of the peripheral circuits are disposed on the memory die, such as a sense amplifier. In the prior art, a serial-parallel conversion circuit and a high-speed interface circuit are disposed on the memory die. After the data readout from the memory cell array is serialized by the serial-parallel conversion circuit, the data is sent to the logic die through the TSV by the high-speed interface circuit, and then sent to the processor through the logic die. The write data received from the processor is also sent to the memory die through the TSV first, and then written into the memory cell array after parallelized by the serial-parallel conversion circuit. The power consumption of the serial-parallel conversion circuit and the high-speed interface is relatively high, and the manufacturing of the serial-parallel conversion circuit and the high-speed interface circuit in the memory die requires more advanced process, which is relatively costly.

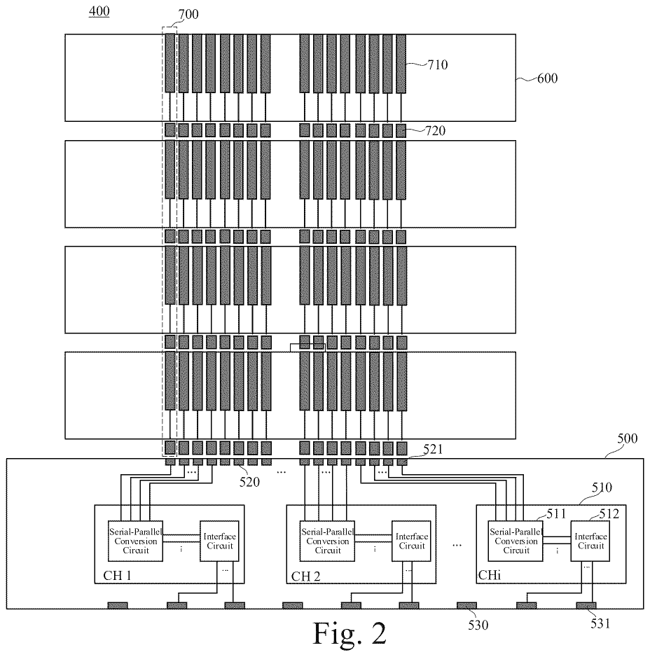

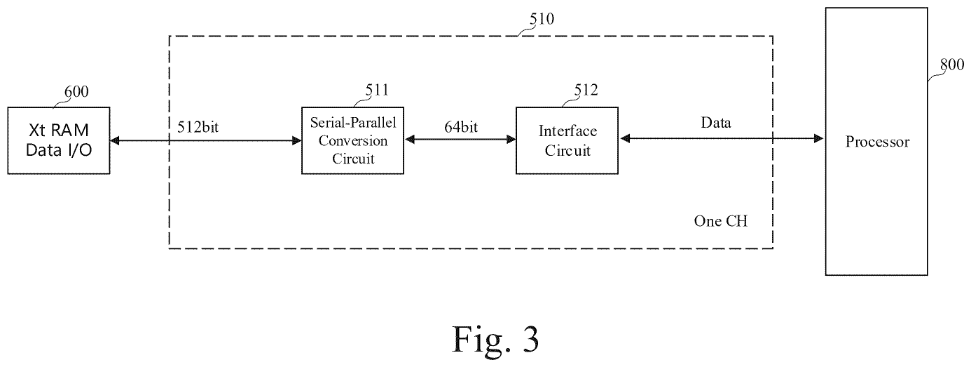

Examples of the present disclosure propose relocating the serial-parallel conversion circuit and the high-speed interface circuit to the logic die. FIG. 2 is a first schematic diagram of a semiconductor device according to an example of the present disclosure, and FIG. 3 is a schematic diagram of data transmission of any data processing unit. Referring to FIGS. 2 and 3, the semiconductor device 400 comprises a logic die 500 and a plurality of memory dies 600 stacked on the logic die 500 along a first direction, wherein the logic die 500 comprises a plurality of data processing units 510, wherein each of the data processing units 510 comprises: an interface circuit 512; and a serial-parallel conversion circuit 511 coupled to the interface circuit 512 and at least one of the memory dies 600.

The serial-parallel conversion circuit 511 is configured to serialize first readout data with a bit width of M output by the at least one of the memory dies 600 to obtain second readout data with a bit width of N; the interface circuit 512 is configured to output the second readout data to a processor.

The interface circuit 512 is further configured to receive first write data with a bit width of N from the processor and transmit the first write data to the serial-parallel conversion circuit 511; the serial-parallel conversion circuit 511 is further configured to parallelize the first write data to obtain second write data with a bit width of M and transmit the second write data to the at least one of the memory dies, wherein M and N are positive integers, and M/N is greater than or equal to 2.

In this example, the first direction may also be referred to as a stacking direction, which is perpendicular to the plane where the logic die 500 is located. In the semiconductor device 400 shown in FIG. 2, four memory dies 600 are stacked on the logic die 500 along the first direction, but it should be understood that the number of the memory dies 600 is not limited thereto, and in other examples, the number of the memory dies 600 may also be 6, 8, 12, 16, or even more. The present disclosure does not limit the number of the memory dies, and more memory dies may be stacked on the logic die.

The plurality of memory dies 600 may be coupled to the logic die 500 by a plurality of electrical connectors 700 penetrating through the plurality of memory dies 600 and extending to the logic die 500. The logic die 500 comprises a plurality of data processing units 510, and the physical structure of each data processing unit 510 may be the same, that is, each data processing unit 510 may comprise a same circuit. The number of the data processing units 510 is equal to the number of channels, wherein each independent channel corresponds to one data processing unit, and a data processing unit corresponding to the channel is configured to process data transmitted in one channel. The semiconductor device shown in FIG. 2 has i independent channels CH1, CH2, . . . , Chi, wherein the logic die 500 comprises i data processing units 510 corresponding to i channels CH1, CH2, . . . , Chi.

Each data processing unit 510 comprises the serial-parallel conversion circuit 511 and the interface circuit 512. The serial-parallel conversion circuit 511 is coupled to at least one of the memory dies 600 among the plurality of memory dies 600. It is understood that in some examples, the serial-parallel conversion circuit 511 is coupled to one memory die 600. In some other examples, the serial-parallel conversion circuit 511 is coupled to two or more memory dies 600. The memory cell array within each memory die 600 may comprise a plurality of banks. In examples in which the serial-parallel conversion circuit 511 is coupled to one memory die 600, the serial-parallel conversion circuit 511 may be coupled to all banks within one memory die 600, or may be coupled to a number of banks within one memory die 600. In examples in which the serial-parallel conversion circuit is coupled to two or more memory dies, the serial-parallel conversion circuit 511 may be coupled to a number of banks in each of the two or more memory dies 600. Also, the same number of banks within each of the memory dies are coupled to the same serial-parallel conversion circuit.

In the operation of reading data, one or more memory dies coupled to the serial-parallel conversion circuit 511 transmit the first readout data with the bit width of M to the serial-parallel conversion circuit 511 through one channel. Bit width refers to the number of data bits transmitted in parallel in a channel. For example, the bit width M of the first readout data may be 2ⁿ, such as 64, 128, 256, 1024, or the like. The serial-parallel conversion circuit 511 may serialize the first readout data with a bit width of M to obtain second readout data with a bit width of N, wherein N may also be 2ⁿ. Since the serial-parallel conversion circuit serializes the first readout data, N is less than M. N is, for example, 32, 64, 128, 256, or the like.

Serialization refers to the conversion of parallel data into serial data. In this example, the serial-parallel conversion circuit 511 may convert each m-bit data of the M-bit parallel-transmitted data into a series of serial data, wherein M is configured as an integer multiple N of m, that is, M=m*N. Then, the M-bit parallel-transmitted data can be converted into N series of serial data, each comprising m-bit serial data. N series of serial data is output from the serial-parallel conversion circuit simultaneously, forming second readout data with a bit width of N. It should be noted that the semiconductor device is configured such that, in response to a read command, the one or more memory dies 600 transmit data with the bit width of M to the serial-parallel conversion unit through one channel at a time, that is, the M-bit parallel-transmitted first readout data is accurately converted into the second readout data with the bit width of N, with neither data loss nor surplus.

The interface circuit 512 is coupled to the serial-parallel conversion circuit 511 and the processor 800. The processor 800 may be various processors 120 in FIG. 1, such as CPUs, GPUs, SOCs, etc. The interface circuit 512 may output the second readout data with the bit width of N to the processor 800.

In the operation of writing data, the interface circuit 512 receives the first write data with the bit width of N transmitted by the processor 800, and transmits the first write data to the serial-parallel conversion circuit 511. The serial-parallel conversion circuit 511 parallelizes the first write data with the bit width of N to obtain second write data with a bit width of M, and transmits the second write data to a corresponding memory die 600.

Parallelization refers to the conversion of serial data into parallel-transmitted data. In this example, the first write data with the bit width of N comprises N series of serial data, which is simultaneously transmitted to the serial-parallel conversion circuit 511. The serial-parallel conversion circuit 511 may convert the m-bit data in each series of serial data into m-bit parallel data. The N series of serial data is parallelized simultaneously, so that m*N-bit parallel data (M-bit parallel-transmitted data) may be obtained, thereby forming the second write data with the bit width of M. It should be noted that, the processor 800 is configured to such that each of the N series of serial data comprises an integer multiple of m-bit serial data. In other words, the N series of serial data may be accurately converted into a complete M-bit parallel data set, with neither data loss nor surplus.

In the examples of the present disclosure, by disposing the serial-parallel conversion circuit 511 and the interface circuit 512 on the logic die 500 instead of the memory die 600, the following advantages are achieved. Firstly, the area of the memory die 600 can be reduced. Also, since the logic die 500 itself can be fabricated using more advanced technology, the serial-parallel conversion circuit 511 and the interface circuit 512 can be implemented in a smaller area, which facilitates the overall miniaturization of the semiconductor device. Secondly, after relocating the serial-parallel conversion circuit 511 and the interface circuit 512 from the memory die 600, the memory die 600 mainly comprises a memory cell array and electrical connectors, and the manufacturing difficulty thereof is lower than that of the serial-parallel conversion circuit 511 and the interface circuit 512. Thus, the manufacturing difficulty of the memory die 600 can be reduced, and the cost of the memory die 600 can be reduced, the layout difficulty of the memory die 600 can also be reduced, thus the design difficulty can be reduced, which facilitates the improvement of the manufacturing yield and the reliability of the device. Thirdly, since the power consumption of the serial-parallel conversion circuit 511 and the interface circuit 512 is relatively high, so the serial-parallel conversion circuit 511 and the interface circuit 512 can be relocated to the logic die 500 and manufactured using more advanced technology. This reduces the power consumption of the serial-parallel conversion circuit 511 and the interface circuit 512, thereby reducing the overall power consumption of the semiconductor device. In addition, when the serial-parallel conversion circuit 511 is relocated to the logic die 500, the channel design is more flexible. Based on the above analysis, if the serial-parallel conversion circuit 511 is located on the memory die 600, it could only receive data from a single memory die 600, limiting each channel to correspond to one memory die 600. In contrast, in this example, the serial-parallel conversion circuit 511 is disposed on the logic die 500, enabling it to exchange data with one or more memory dies 600. In this case, the data in one channel may come from one or more memory dies 600, that is, the channel may correspond to one or more memory dies 600. The configuration of the channel is more flexible, which facilitates optimization algorithms to achieve higher memory performance.

In some examples, M/N is a positive integer power of 2 (2ⁿ), and M/N is greater than or equal to 8. For example, M/N may be 8, 16, 32, 64, or the like.

M/N is equal to m describe above. The present disclosure takes M/N (that is, m) being equal to 8 as an example for illustration. The serial-parallel conversion circuit may serialize every 8-bit data in the M-bit parallel first readout data to obtain N series of serial data, wherein each series of serial data comprises 8-bit serial data. The N series of serial data are simultaneously output, forming the second readout data with a bit width of N. The serial-parallel conversion circuit may further convert the 8-bit data in each of the N series of serial data input simultaneously into 8-bit parallel data to obtain 8N (i.e., M)-bit parallel data, forming the second write data with a bit width of M. For a case where M/N is another value, reference may be made to this case, and details are not described herein again.

In some examples, as shown in FIG. 3, M may be 512, and N may be 64. Then, the serial-parallel conversion unit 511 may serialize the first readout data with a bit width of 512 bits into the second readout data with a bit width of 64 bits, and send the second readout data to the interface circuit. The serial-parallel conversion circuit 511 may further parallelize the first write data with a bit width of 64 bits into the second write data with a bit width of 512 bits, and send the second write data to the corresponding memory die through one channel. It should be noted that, in any channel, the data processing unit 510 may independently perform the data serial-parallel conversion operation according to the examples of the present disclosure.

In some examples, the memory die 600 transmits the first readout data to the serial-parallel conversion circuit 511 at a first transmission rate, and the serial-parallel conversion circuit 511 transmits the second readout data to the interface circuit 512 at a second transmission rate, wherein a ratio of the first transmission rate to the second transmission rate is N/M.

The transmission rate refers to the number of bits transmitted per second. The unit of transmission rate may be bits/second (bps). When the product of the first transmission rate and the bit width M is equal to the product of the second transmission rate and the bit width N, the memory die 600 transmits the first readout data with the bit width of M at the first transmission rate, the serial-parallel conversion circuit 511 may transmit the second readout data with the bit width of N to the interface circuit 512 at the second transmission rate.

In some examples, the memory die 600 may transmit first readout data with a bit width of 512 bits at a first transmission rate of 0.8 Gbps, the serial-parallel conversion circuit 511 may serialize the first readout data with the bit width of 512 bits into second readout data with a bit width of 64 bits, and output the second readout data to the interface circuit 512 at a greater second transmission rate of 6.4 Gbps.

For example, the interface circuit 512 may comprise a high-speed interface circuit, and may output the second readout data with the bit width of 64 bits to the processor 800 at the second transmission rate of 6.4 Gbps.

In some examples, the interface circuit 512 transmits the first write data to the serial-parallel conversion circuit 511 at the second transmission rate, and the serial-parallel conversion circuit 511 transmits the second write data to the memory die 600 at the first transmission rate.

The processor 800 may transmit first write data with a bit width of N bits to the interface circuit 512 at a second transmission rate, and the interface circuit 512 may receive the first write data with the bit width of N bits and transmit the first write data to the serial-parallel conversion circuit 511 at the second transmission rate. When the product of the second transmission rate and the bit width N is equal to the product of the first transmission rate and the bit width M, the interface circuit 512 transmits the first write data with the bit width of N at the second transmission rate, the serial-parallel conversion circuit 511 may transmit the second write data with the bit width of M at the first transmission rate.

In some examples, the processor 800 and the interface circuit 512 may transmit the first write data with a bit width of 64 bits at a second transmission rate of 6.4 Gbps. The serial-parallel conversion circuit 511 may parallelize the first write data with so that bit width of 64 bits into second write data with a bit width of 512 bits, and output the second write data to the memory die 600 at a lower first transmission rate of 0.8 Gbps.

In the examples of the present disclosure, the serial-parallel conversion circuit 511 and the interface circuit 512 are relocated from the memory die 600 to the process-advanced logic die 500, so that the memory die 600 can complete data transmission between the memory die and the logic die at a transmission rate of N/M (for example, ⅛) of the semiconductor device interface through a bit width of M/N (for example, 8) times that of the semiconductor device interface. The semiconductor device refers to a device composed of memory dies and a logic die, and the bit width of the semiconductor device interface refers to the amount of data transferred once between the logic die and the processor. In this way, the data transmission rate between the memory die 600 and the logic die 500 can be reduced, and the power consumption of transferring data from the memory die 600 to the logic die 500 is reduced, thereby reducing the overall power consumption of the semiconductor device. In addition, after the data transmission rate between the memory die 600 and the logic die 500 is reduced, the requirements on the cross-sectional size of the electrical connector 700 and the pitch between the adjacent electrical connectors 700 are reduced, which facilitates reducing the cross-sectional size of the electrical connector 700 and the pitch between adjacent electrical connectors 700.

In some examples, with continued reference to FIG. 2, the logic die 500 further comprises a first number of first data pads 521 and a second number of second data pads 531, wherein serial-parallel conversion circuits 511 of the plurality of data processing units 510 are coupled to the plurality of memory dies 600 via the first number of first data pads 521, and interface circuits 512 of the plurality of data processing units 510 are coupled to the processor via the second number of second data pads 531, and wherein a ratio of the first number to the second number is equal to M/N.

As shown in FIG. 2, the logic die 500 is provided with a plurality of first pads 520 on a first side facing the memory die 600 and a plurality of second pads 530 on a second side opposite to the memory die 600. The plurality of first pads 520 comprises the first number of first data pads 521. The first number of first data pads are to form a first number of first data pins. For example, the first data pin is a bidirectional pin and has both data input and a data output functions. That is, the logic die 500 may receive the first readout data from the memory die 600 through the first data pads 521, or may send the second write data to the memory die 600 through the first data pads 521.

The logic die 500 may comprise i data processing units 510 corresponding to i channels CH1-CHi, and the serial-parallel conversion circuit 511 of each data processing unit 510 may be coupled to M first data pads 521. In this case, the first number of the first data pads 521 is i*M. As shown in FIG. 2, each first data pad 521 is correspondingly connected to one electrical connector 700, and i*M first data pads 521 enable serial-parallel conversion circuits 511 in all data processing units 510 to be coupled to the plurality of memory dies 600.

With continued reference to FIG. 2, the plurality of second pads 530 comprises the second number of second data pads 531. The second number of second data pads 531 are to form a second number of second data pins. For example, the second data pin is a bidirectional pin and has both data input and a data output functions. That is, the logic die 500 may receive the first write data from the processor 800 through the second data pads 531, or may send the second readout data to the processor 800 through the second data pads 531.

The interface circuit 512 of each data processing unit 510 may be coupled to the N second data pads 531, and in this case, the second number of the second data pads 531 is i*N. The i*N second data pads 531 enable the interface circuits 512 in all data processing units 510 to be coupled to processor 800.

Based on the above analysis, it can be seen that the ratio of the first number to the second number is (i*M)/(i*N)=M/N. The number of the first data pads 521 coupled to each serial-parallel conversion circuit 511 corresponds to the bit width M of the first readout data or the second write data. When one channel transmits M-bit first readout data or M-bit second write data, each first data pad 521 transmits one-bit data. The number of the second data pads 531 coupled to each interface circuit 512 corresponds to the bit width of the semiconductor device interface. In the case that the semiconductor device transmits N-bit second readout data to the processor 800 or receives N-bit first write data from the processor, each second data pad 531 transmits one-bit data.

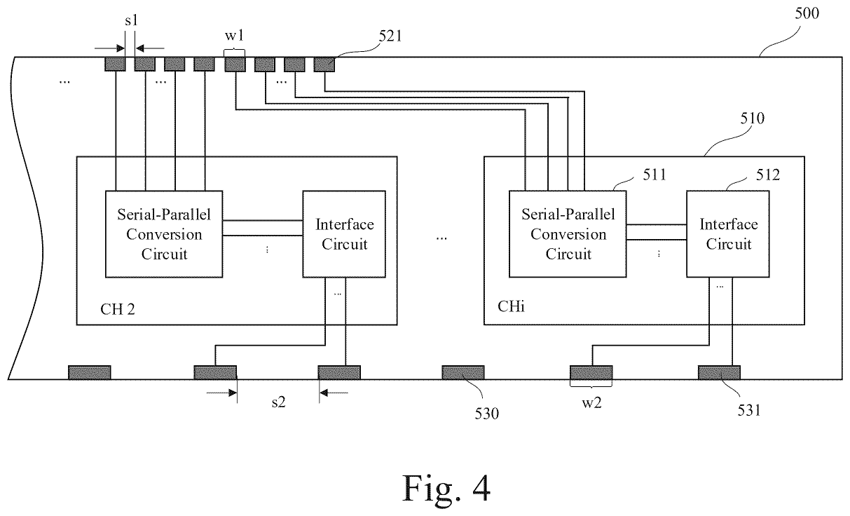

FIG. 4 is a partial enlarged view of a logic die shown in FIG. 2. In some examples, as shown in FIG. 4, a first pitch s1 between two adjacent first data pads 521 is smaller than a second pitch w2 between two adjacent second data pads 531.

In some examples, a size of a first cross section of the first data pad 521 perpendicular to a stacking direction (i.e., the first direction) is smaller than a size of a second cross section of the second data pad 531 perpendicular to the stacking direction. For example, the size of the first cross section may be a width w1 of the first cross section, and the size of the second cross section may be a width w2 of the second cross section, wherein w1 is less than w2.

In the example in which the serial-parallel conversion circuit is located on the memory die, the data of the bit width N is transmitted between the memory die and the logic die, then i*N first data pads 521 may be configured, which is relatively fewer. In contrast, in this example, i*M first data pads 521 are configured, which is relatively more, thus at least one of the size w1 of the first cross section of the first data pad 521 or the first pitch s1 of the adjacent first data pads 521 may be reduced, thereby enabling the first side of the logic die 500 to accommodate more first data pads 521. Moreover, since the data transmission rate between the memory die 600 and the logic die 500 is reduced, the reduction of the size w1 of the first cross-sectional and the first pitch s1 would not affect the performance of data transmission.

In addition, in this example, the second readout data and the first write data of the bit width N are transmitted between the interface circuit 512 and the processor 800, so i*N second data pads 531 may be configured, which is fewer compared with the first data pads 521, allowing the second pitch s2 of the second data pads 531 may be designed to be larger. This reduces the layout difficulty of the circuit in the logic die 500, and increases the pitch between conductive lines coupled to the second data pads 531 to reduce the coupling effect. Furthermore, the size of the second cross section of the second data pad 531 is designed to be larger, which can reduce the difficulty of alignment with the pads on the interposer (e.g., interposer 130 in FIG. 1) and improve the reliability of connection with the pads on the interposer.

In other examples, the second pitch between adjacent second data pads 531 may also be equal to the first pitch between adjacent first data pads 521. Alternatively, the size of the second cross section of the second data pad 531 may also be equal to the size of the first cross section of the first data pad 521.

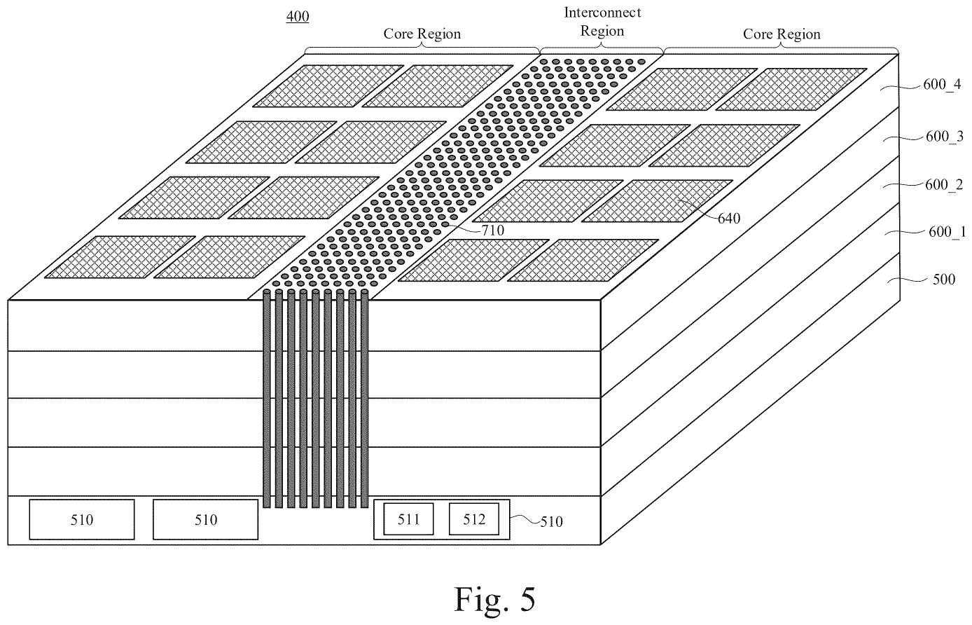

FIG. 5 is a second schematic diagram of a semiconductor device according to an example of the present disclosure. In some examples, as shown in FIG. 2 and FIG. 5, a plurality of connection structures extending along the stacking direction are formed in each of the memory dies 600, the plurality of connection structures in two adjacent memory dies 600 are correspondingly coupled, the plurality of connection structures in a memory die 600 adjacent to the logic die 500 are coupled to a plurality of first pads 520 of the logic die 500, and the plurality of first pads 520 comprise the first number of first data pads 521.

For example, the connection structure may comprise a through silicon via 710. The present disclosure takes the connection structure being the through silicon via 710 as an example for illustration, and in other examples, the connection structure may also be implemented by other structures.

As shown in FIG. 5, each of the memory dies 600-1, 600-2, 600-3, 600-4 comprises a core region and an interconnect region, and a memory cell array is formed in the core region. For example, the memory cell array may be divided into a plurality of banks 640, and the number of the banks 640 may be 8,16, 32,64, etc. In some examples, the banks 640 may also be organized into bank groups each comprising a plurality of banks 640. Each bank 640 may be activated separately to perform read and write operations, or the like.

A plurality of through silicon vias 710 extending along the stacking direction are formed in the interconnect region, and the plurality of through silicon vias 710 are arranged in an array. The stacking direction is perpendicular to the plane where the logic die or the memory die is located, and in this example, the stacking direction is the vertical direction. Each of the memory dies 600-1, 600-2, 600-3, 600-4 may comprise the same number of through silicon vias 710, and all through silicon vias in adjacent memory dies 600 are correspondingly coupled. A string of through silicon vias 710 located in different memory dies 600-1, 600-2, 600-3, 600-4 and coupled to each other are one example of the electrical connectors 700, wherein the plurality of memory dies 600-1, 600-2, 600-3, 600-4 may be coupled to the logic die 500. Referring back to FIG. 2, the through silicon vias 710 in adjacent memory dies 600 may be coupled by pad structures formed on the surface of the memory dies 600. The pad structures may comprise bumps 720.

Referring back to FIG. 2, the plurality of through silicon vias 710 of the memory die 600 adjacent to the logic die 500 are coupled in a one-to-one correspondence to the plurality of first pads 520 of the logic die 500. The number of the through silicon vias 710 is equal to the number of the first pads 520. Among the plurality of through silicon vias 710, the through silicon vias coupled to the first data pads 521 (i.e., the connection structures coupled to the first data pads) are data through silicon vias for data transmission. The number of the data through silicon vias is equal to the number of the first data pads 521, which both are the first number. The data through silicon via may transmit data bi-directionally, that is, can not only transmit the first readout data to the logic die 500, but also transmit the second write data to the memory die 600.

In some examples, the number of data through silicon vias in each memory die 600 is i*M, i is the number of channels as well as the number of data processing units 510, and the number of data through silicon vias, which is used for transmitting the first readout data of the bit width M or the second write data of the bit width M, coupled to the serial-parallel conversion circuit 511 in one data processing unit 510 is M.

For example, when the bit width M is 512 bits and the number of channels is 16, the number of data through silicon vias is 8192. That is, 8192 data through silicon vias are configured within each memory die 600. In this example, more data through silicon vias may be placed within the memory die 600 by at least one of reducing the size of the cross section of the data through silicon via perpendicular to the stacking direction or reducing the pitch between adjacent data through silicon vias without affecting the area of the core region. In a specific example, since the size of the cross section of the data through silicon via is reduced and the pitch between adjacent data through silicon vias is reduced, even if the number of the data through silicon vias is increased, the area of the interconnect region is not increased, so that the area of the core region is not affected, and the area of the memory die 600 is not increased. Rather, since the serial-parallel conversion circuit 511 and the interface circuit 512 are relocated, the area of the memory die 600 can be reduced.

The sizes of cross-sections of the data through silicon vias and other through silicon vias (e.g., through silicon vias for transmitting commands or addresses) may be the same or not. In one example, the sizes of cross-sections of all through silicon vias 710 may be the same.

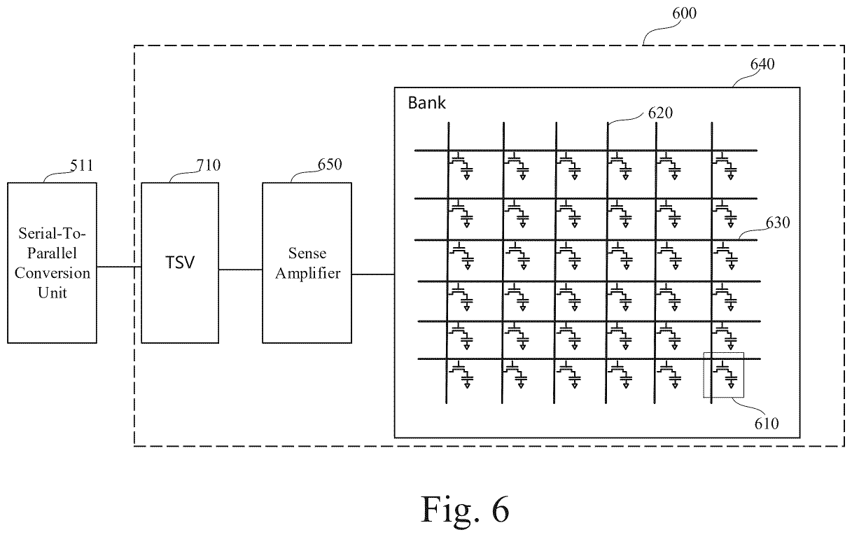

FIG. 6 is a schematic diagram of a memory die according to an example of the present disclosure. In some examples, as shown in FIG. 6, each memory die 600 further comprises a plurality of bit lines 620 and a plurality of sense amplifiers 650, wherein the plurality of bit lines 620 are coupled to the memory cell array, and the plurality of sense amplifiers 650 are coupled to the plurality of bit lines 620 and the data through silicon via 710 coupled to the first data pad 521 among the plurality of through silicon vias 710, and wherein a rate at which the sense amplifier 650 transmits data is equal to a rate at which the data through silicon via 710 transmits data and is equal to a first transmission rate.

FIG. 6 shows one bank 640 within memory die 600, while other banks are as same as the bank 640. As shown in FIG. 6, the bank 640 may comprise a plurality of rows of memory cells and a plurality of columns of memory cells. The memory cells 610 in the row of memory cells are coupled to the same word line 630, which selects which of the plurality of rows of memory cells is activated to perform a read or write operation. The memory cells 610 in the column of memory cells are coupled to the same bit line 620, that is, the bit line 620 is connected to the first sources/drains of the memory cells 610 in the same column. The bit line 620 may select one column of memory cells to be activated, or in a burst mode, the bit line 620 may also select a plurality of columns of memory cells to be activated.

Each memory cell 610 may be a 1T1C cell composed of one transistor and one capacitor. The capacitor stores one bit of data in the form of a charge or an electron. In one example, a higher charge level in the capacitor may represent data “1”, while a lower charge level may represent data “0”. The transistor is configured for accessing and reading/writing data, wherein the gate of the transistor is connected with the word line 630, the first source/drain is connected with the bit line 620, and the second source/drain is connected with the capacitor. The electrical signal applied to the word line 630 can control the transistor to be turned on or off. When the transistor is turned on, the capacitor conducts with the bit line 620, enabling electrons to flow through the bit line 620 into the capacitor for writing data “1”, or allowing the capacitor to discharge through the bit line 620 for writing data “0”. When the transistor is turned off, the capacitor is isolated from the bit line 620, thereby retaining previously written data or charge. In addition, the data stored in the capacitor may also be read by sensing the amount of charges.

A plurality of sense amplifiers 650 are coupled to the bank 640. For example, sense amplifiers 650 may be coupled to two bit lines 620 in the bank 640, and two bit lines 620 coupled to the same sense amplifier 650 are configured to not be activated at the same time. Also, for example, sense amplifier 650 may be coupled to each bit line 620 within two banks 640. The coupling manner of the sense amplifier 650 and the bit line 620 is not limited in the present disclosure.

For example, the sense amplifiers 650 may be directly coupled to the data through silicon vias 710. Also, for example, a gating circuit, a data bus driver, and the like may also be disposed between the sense amplifiers 650 and the data through silicon vias 710. The gating circuit is controlled to be turned on or off by a signal to decide which of the banks 640 is to output data. The data bus driver can adjust the amplitude of the data signal.

In a data reading operation, the sense amplifiers 650 can readout data in the memory cells, and the sense amplifiers 650 can output data at a first transmission rate. The M sense amplifiers 650 are configured to simultaneously output data to form first readout data of bit width M. The first readout data is transmitted to the data through silicon vias 710 at the first transmission rate. That is, in the memory die 600, the serial-parallel conversion circuit 511 and the interface circuit 512 are not disposed on the path from the sense amplifiers 650 to the data through silicon vias 710, and the first readout data is transmitted to the data through silicon vias 710 at a rate at which it is output from the sense amplifiers 650. The data through silicon vias 710 further transmit the first readout data of the bit width M to the serial-parallel conversion circuit 511 in the logic die 500 at the first transmission rate.

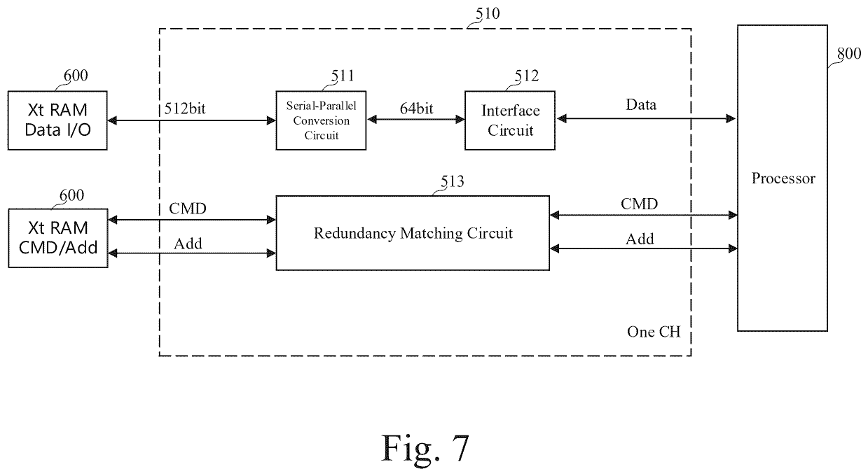

FIG. 7 is a schematic diagram of a data processing unit according to an example of the present disclosure. In some examples, as shown in FIG. 7, each data processing unit 510 further comprises: a redundancy matching circuit 513 coupled to the corresponding at least one of the memory dies 600 and the processor 800 and configured to: receive the command CMD and the address Add sent by the processor 800, and send the command CMD and the address Add to the memory die 600 as indicated by the address Add.

The redundancy matching circuit 513 is further configured to: replace the address corresponding to the selected memory cell as indicated by the address Add with a redundant address and transmit the redundant address to the memory die 600, if data cannot be written to the selected memory cell. For example, the failure to write data to the selected memory cell as indicated by the address Add may result from a defective selected memory cell or a faulty data path between the data processing unit 510 and the selected memory cell as indicated by the address Add.

In this example, the serial-parallel conversion circuit 511, the interface circuit 512 and the redundancy matching circuit 513 in the data processing unit 510 are configured to support one channel CH to transmit data independently. The memory die 600 coupled to the serial-parallel conversion circuit 511 is the same as the memory die 600 coupled to the redundancy matching circuit 513.

In some examples, the serial-parallel conversion circuit 511 comprises a serializer-deserializer (SERDES). The serializer is configured to serialize the first readout data with a bit width of M output by the memory die to obtain the second readout data with a bit width of N. The deserializer is configured to parallelize the first write data with a bit width of N to obtain the second write data with a bit width of M and transmit the second write data to the memory die 600.

In some examples, the logic die 500 may further comprise other circuits such as a test interface and a cache unit (for example, a static random access memory (SRAM)), wherein the test interface and the cache unit may be shared by all the channels (CH).

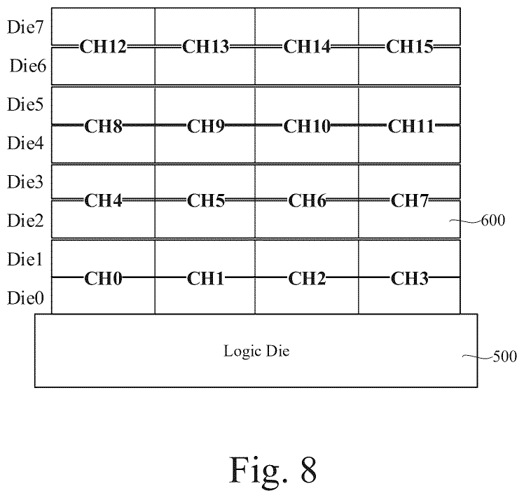

FIG. 8 is a schematic diagram of a channel according to an example of the present disclosure. Each memory die 600 may comprise a plurality of banks (e.g., banks 640 in FIGS. 5 and 6). For example, one channel may be coupled to banks of different memory dies 600. For example, in FIG. 8, any one of channels CH0 through CH15 is coupled to banks of two memory dies 600, and each channel is coupled to a number of banks within the memory die 600. Taking the channel CH0 as an example, the channel CH0 may be coupled to ¼ banks in each of the memory dies Die0 and Die1. This channel setting manner benefits from the relocation of the serial-parallel conversion circuit 511 and the interface circuit 512 to the logic die 500 in the present disclosure, so that the channel setting manner is more flexible, which facilitates to optimize the memory performance through an algorithm.

FIG. 8 shows that total 8 memory dies 600 Die0 to Die 7 may comprise 16 channels. In other examples, 16 channels may also be implemented by 16 memory dies 600. The numbers of memory dies 600 and channels are not related, and in different examples, the number of channels may be configured as desired.

It should also be noted that, in other examples, the channel may only be coupled to a bank in one memory die 600. The channels may be coupled to all banks within one memory die 600. Alternatively, the channel may also be coupled to a number of banks within one memory die 600, and in this case, one memory die 600 may comprise a plurality of channels.

The semiconductor device 400 according to the example of the present disclosure may comprise the memory 200 formed by the logic die 210 and the memory die 220 in FIG. 1. The semiconductor device 400 may comprise a high bandwidth memory (HBM).

An example of the present disclosure further provides a memory, comprising: a plurality of memory dies and a logic die, wherein the logic die and the plurality of memory dies are stacked in a stacking first direction, and the logic die comprising: a serial-parallel conversion circuit and an interface circuit, wherein the serial-parallel conversion circuit is coupled to at least one of the memory dies, and the interface circuit is coupled to the serial-parallel conversion circuit and a peripheral device;
wherein the serial-parallel conversion circuit is configured to: transmit data with a bit width of M at a first transmission rate to a corresponding memory die; and transmit data with a bit width of N at a second transmission rate to the interface circuit directly, wherein M and N are positive integers, and M/N is greater than or equal to 2.

In some examples, the M/N is a positive integer power of 2, and the M/N is greater than or equal to 8.

In some examples, a ratio of the first transmission rate to the second transmission rate is N/M.

In some examples, the logic die further comprises: a first number of first data pads, wherein the serial-parallel conversion circuit is coupled to the plurality of memory dies via a corresponding first data pad; and a second number of second data pads, wherein the interface circuit is coupled to the peripheral device via a corresponding second data pad, and wherein a ratio of the first number to the second number is equal to M/N.

In some examples, a first pitch between two adjacent first data pads among the first data pads is smaller than a second pitch between two adjacent second data pads among the second data pads.

In some examples, a size of a first cross section of each of the first data pads perpendicular to the first direction is smaller than a size of a second cross section of each of the second data pads perpendicular to the first direction.

In some examples, a plurality of connection structures extending along the first direction are formed in each of the memory dies, the plurality of connection structures in two adjacent memory dies are correspondingly coupled, the plurality of connection structures in a memory die adjacent to the logic die are coupled to a plurality of first pads of the logic die, and the plurality of first pads comprise the first number of first data pads.

Each of the memory dies further comprises a memory cell array, a plurality of bit lines and a plurality of sense amplifiers, wherein the plurality of bit lines are coupled to the memory cell array, and the plurality of sense amplifiers are coupled to the plurality of bit lines and connection structures coupled to the first data pads among the plurality of connection structures, wherein a rate at which the sense amplifiers output data is equal to a rate at which the connection structures transmit data and is equal to the first transmission rate.

The memory provided by the example may comprise the semiconductor device 400 described above, and has the technical features and corresponding effects of the semiconductor device 400. The memory may comprise high bandwidth memory (HBM). The semiconductor device 400 or memory may be packaged separately, or may be integrated in a system which is integrally packaged.

An example of the present disclosure further provides a system, comprising: one of a semiconductor device or a memory, and a processor, wherein the semiconductor device may comprise the semiconductor device according to any one of the above examples, and the memory may comprise the memory according to any one of the above examples. The processor is coupled to the logic die in the semiconductor device or the memory and is configured to transmit the first write data to the logic die or read the second read data from the logic die.

In some examples, the semiconductor device and the processor may be integrated in the same package. For example, the system may also comprise an interposer and a package substrate. The semiconductor device and the processor are disposed on the interposer, and the interposer is disposed on the package substrate. The interposer may comprise, for example, the interposer 130 shown in FIG. 1, the package substrate 140 may comprise, for example, the package substrate 140 shown in FIG. 1, and the system may comprise, for example, the system 100 shown in FIG. 1.

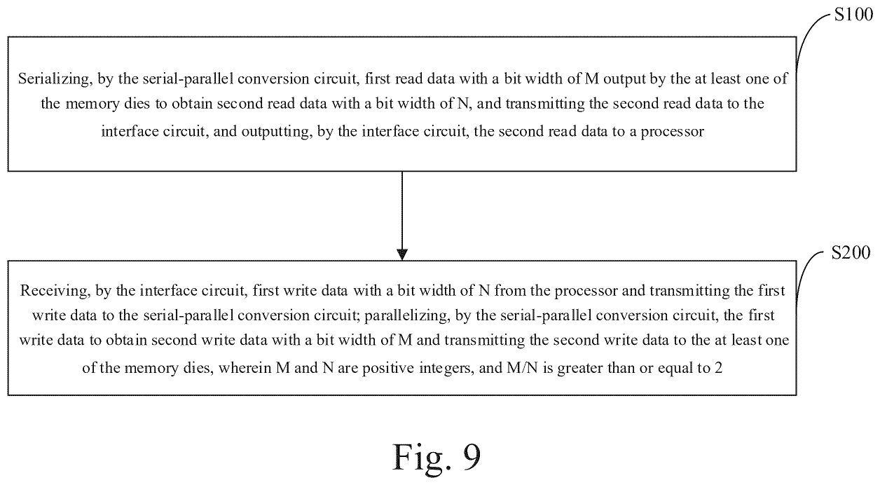

An example of the present disclosure further provides a method of data processing, FIG. 9 is a schematic flowchart of a method of data processing according to an example of the present disclosure. The method of data processing may be applied to the semiconductor device or the memory described in any example of the present disclosure, wherein the semiconductor device or the memory comprises a logic die and a plurality of memory dies, the logic die comprises a plurality of data processing units each comprising a serial-parallel conversion circuit and an interface circuit, and the serial-parallel conversion circuit is coupled to the memory die and the interface circuit. As shown in FIG. 9, the method of data processing comprises:

S100: serializing, by the serial-parallel conversion circuit, first read data with a bit width of M output by the at least one of the memory dies to obtain second read data with a bit width of N, and transmitting the second read data to the interface circuit, and outputting, by the interface circuit, the second read data to a processor;

S200: receiving, by the interface circuit, first write data with a bit width of N from the processor and transmitting the first write data to the serial-parallel conversion circuit; and parallelizing, by the serial-parallel conversion circuit, the first write data to obtain second write data with a bit width of M and transmitting the second write data to the at least one of the memory dies, wherein M and N are positive integers, and M/N is greater than or equal to 2.

It should be noted that the present disclosure does not limit the execution sequence of operations S100 and S200. It is understood that operation S100 is performed in a data read operation, operation S200 is performed in a data write operation, operations S100 and S200 are not in a particular order, and any other operations may be added between the two operations.

In the examples of the present disclosure, by disposing the serial-parallel conversion circuit and the interface circuit on the logic die instead of the memory die, the following advantages are achieved. Firstly, the area of the memory die can be reduced. Also, since the logic die itself can be fabricated using more advanced technology, the serial-parallel conversion circuit and the interface circuit can be implemented in a smaller area, which facilitates the overall miniaturization of the semiconductor device. Secondly, after relocating the serial-parallel conversion circuit and the interface circuit from the memory die, the memory die mainly comprises a memory cell array and connection structures (for example, through silicon vias, TSV), and the manufacturing difficulty thereof is lower than that of the serial-parallel conversion circuit and the interface circuit. Thus, the manufacturing difficulty of the memory die can be reduced, and the cost of the memory die can be reduced, the layout difficulty of the memory die can also be reduced, thus the design difficulty can be reduced, which facilitates the improvement of the manufacturing yield and the reliability of the device. Thirdly, since the power consumption of the serial-parallel conversion circuit and the interface circuit is relatively high, so the serial-parallel conversion circuit and the interface circuit can be relocated to the logic die and manufactured using more advanced technology. This reduces the power consumption of the serial-parallel conversion circuit and the interface circuit, thereby reducing the overall power consumption of the semiconductor device. In addition, when the serial-parallel conversion circuit is relocated to the logic die, the channel design is more flexible. It can be understood that if the serial-parallel conversion circuit is located in the memory die, it could only receive data from a single memory die, limiting each channel to correspond to one memory die. In contrast, in this example, the serial-parallel conversion circuit is disposed on the logic die, enabling it to exchange data with one or more memory dies. In this case, the data in one channel may come from one or more memory dies, that is, the channel may correspond to one or more memory dies. The configuration of the channel is more flexible, which facilitates optimization algorithms to achieve higher memory performance.

In some examples, the method of data processing further comprises: transmitting, by the memory dies, the first read data to the serial-parallel conversion circuit at a first transmission rate.

Transmitting, by the serial-parallel conversion circuit, the second read data to the interface circuit at S100 comprises: transmitting, by the serial-parallel conversion circuit, the second read data to the interface circuit at a second transmission rate, wherein a ratio of the first transmission rate to the second transmission rate is N/M.

In some examples, transmitting, by the interface circuit, the first write data to the serial-parallel conversion circuit at S200 comprises: transmitting, by the interface circuit, the first write data to the serial-parallel conversion circuit at a second transmission rate

Transmitting, by the serial-parallel conversion circuit, the second write data to the memory dies at S200 comprises: transmitting, by the serial-parallel conversion circuit, the second write data to the memory dies at a first transmission rate.

In the examples of the present disclosure, the memory die transmits data to/from the logic die at a data rate of N/M (e.g., ⅛) of that of the semiconductor device interface by using a bit width M/N (e.g., 8) times that of the semiconductor device interface. In this way, the data transmission rate between the memory die and the logic die can be reduced, and the power consumption of transferring data from the memory die to the logic die is reduced, thereby reducing the overall power consumption of the semiconductor device. In addition, after the data transmission rate between the memory die and the logic die is reduced, the requirements on the cross-sectional size of the connection structure and the pitch between the adjacent connection structure are reduced, which facilitates reducing the cross-sectional size of the connection structure and the pitch between adjacent connection structure.

The features disclosed in the several apparatus examples provided by the present disclosure may be arbitrarily combined without conflict to obtain a new apparatus example.

The method disclosed in the several method examples provided by the present disclosure may be arbitrarily combined without conflict to obtain a new method example.

The above descriptions are only specific examples of the present disclosure, but the protection scope of the present disclosure is not limited thereto, and changes or replacements that may be easily conceived by any person skilled in the art within the technical scope of the present disclosure should be covered within the protection scope of the present disclosure.

What is claimed is:

1. A semiconductor device, comprising:
a logic die; and
a plurality of memory dies stacked on the logic die along a first direction,
wherein the logic die comprises:
a plurality of data processing units, wherein each of the data processing units comprises:
an interface circuit; and
a serial-parallel conversion circuit coupled to the interface circuit and at least one of the memory dies, wherein the serial-parallel conversion circuit is configured to:
serialize first readout data with a bit width of M output by the at least one of the memory dies to obtain second readout data with a bit width of N;
the interface circuit is configured to:
output the second readout data to a processor; and
receive first write data with a bit width of N from the processor and transmit the first write data to the serial-parallel conversion circuit; and
the serial-parallel conversion circuit is further configured to:
parallelize the first write data to obtain second write data with a bit width of M and transmit the second write data to the at least one of the memory dies, wherein M and N are positive integers, and M/N is greater than or equal to 2.

2. The semiconductor device of claim 1, wherein the M/N is a positive integer power of 2, and the M/N is greater than or equal to 8.

3. The semiconductor device of claim 1, wherein:
the at least one of the memory dies is configured to:
transmit the first readout data to the serial-parallel conversion circuit at a first transmission rate, and
the serial-parallel conversion circuit is configured to:
transmit the second readout data to the interface circuit at a second transmission rate, wherein a ratio of the first transmission rate to the second transmission rate is N/M.

4. The semiconductor device of claim 1, wherein:
the interface circuit is configured to:
transmit the first write data to the serial-parallel conversion circuit at a second transmission rate, and
the serial-parallel conversion circuit is configured to:
transmit the second write data to the at least one of the memory dies at a first transmission rate, wherein a ratio of the first transmission rate to the second transmission rate is N/M.

5. The semiconductor device of claim 1, wherein the logic die further comprises:
a first number of first data pads, wherein a plurality of serial-parallel conversion circuits are coupled to the plurality of memory dies via the first number of first data pads; and
a second number of second data pads, wherein a plurality of interface circuits are coupled to the processor via the second number of second data pads, and
wherein a ratio of the first number to the second number is equal to M/N.

6. The semiconductor device of claim 5, wherein a first pitch between two adjacent first data pads among the first data pads is smaller than a second pitch between two adjacent second data pads among the second data pads.

7. The semiconductor device of claim 6, wherein a size of a first cross section of each of the first data pads perpendicular to the first direction is smaller than a size of a second cross section of each of the second data pads perpendicular to the first direction.

8. The semiconductor device of claim 5, wherein:
a plurality of connection structures extending along the first direction are formed in each of the memory dies, the plurality of connection structures in two adjacent memory dies among the memory dies are correspondingly coupled, the plurality of connection structures in a memory die adjacent to the logic die are coupled to a plurality of first pads of the logic die, and the plurality of first pads comprise the first number of first data pads, and
each of the memory dies further comprises:
a memory cell array;
a plurality of bit lines coupled to the memory cell array; and
a plurality of sense amplifiers coupled to the plurality of bit lines and connection structures coupled to the first data pads among the plurality of connection structures, wherein a rate at which the plurality of sense amplifiers output data is equal to a rate at which the connection structures transmit data.

9. The semiconductor device of claim 8, wherein:
the data processing units comprise i data processing units, and wherein i is a positive integer, and
the connection structures coupled to the first data pads in each of the memory dies comprise i*M connection structures.

10. The semiconductor device of claim 1, wherein the semiconductor device comprises a high bandwidth memory.

11. A memory, comprising:
a plurality of memory dies stacked along a first direction; and
a logic die stacked with the plurality of memory dies along the first direction, wherein the logic die comprises:
a serial-parallel conversion circuit coupled to at least one of the memory dies; and
an interface circuit coupled to the serial-parallel conversion circuit and a peripheral device, wherein the serial-parallel conversion circuit is configured to:
transmit data with a bit width of M at a first transmission rate to a corresponding memory die; and
transmit data with a bit width of N at a second transmission rate to the interface circuit directly,
wherein M and N are positive integers, and M/N is greater than or equal to 2.

12. The memory of claim 11, wherein the M/N is a positive integer power of 2, and the M/N is greater than or equal to 8.

13. The memory of claim 11, wherein a ratio of the first transmission rate to the second transmission rate is N/M.

14. The memory of claim 11, wherein the logic die further comprises:
a first number of first data pads, wherein the serial-parallel conversion circuit is coupled to the plurality of memory dies via a corresponding first data pad; and
a second number of second data pads, wherein the interface circuit is coupled to the peripheral device via a corresponding second data pad, and
wherein a ratio of the first number to the second number is equal to M/N.

15. The memory of claim 14, wherein a first pitch between two adjacent first data pads among the first data pads is smaller than a second pitch between two adjacent second data pads among the second data pads.

16. The memory of claim 15, wherein a size of a first cross section of each of the first data pads perpendicular to the first direction is smaller than a size of a second cross section of each of the second data pads perpendicular to the first direction.

17. The memory of claim 14, wherein:
a plurality of connection structures extending along the first direction are formed in each of the memory dies, the plurality of connection structures in two adjacent memory dies among the memory dies are correspondingly coupled, the plurality of connection structures in a memory die adjacent to the logic die are coupled to a plurality of first pads of the logic die, and the plurality of first pads comprise the first number of first data pads, and
each of the memory dies further comprises:
a memory cell array;
a plurality of bit lines coupled to the memory cell array; and
a plurality of sense amplifiers coupled to the plurality of bit lines and connection structures coupled to the first data pads among the plurality of connection structures, wherein a rate at which the plurality of sense amplifiers output data is equal to a rate at which the connection structures transmit data and is equal to the first transmission rate.

18. The memory of claim 11, wherein the memory comprises a high bandwidth memory.

19. A method of data processing, wherein a semiconductor device comprises:
a plurality of memory dies; and
a logic die comprising a plurality of data processing units, wherein each of the data processing units comprises:
an interface circuit; and
a serial-parallel conversion circuit coupled to at least one of the memory dies and the interface circuit,
wherein the method comprises:
serializing, by the serial-parallel conversion circuit, first readout data with a bit width of M output by the at least one of the memory dies to obtain second readout data with a bit width of N, and transmitting the second readout data to the interface circuit;
outputting, by the interface circuit, the second readout data to a processor;
receiving, by the interface circuit, first write data with a bit width of N from the processor and transmitting the first write data to the serial-parallel conversion circuit; and
parallelizing, by the serial-parallel conversion circuit, the first write data to obtain second write data with a bit width of M and transmitting the second write data to the at least one of the memory dies, wherein M and N are positive integers, and M/N is greater than or equal to 2.

20. The method of claim 19, further comprising:
transmitting, by the at least one of the memory dies, the first readout data to the serial-parallel conversion circuit at a first transmission rate, and
wherein transmitting, by the serial-parallel conversion circuit, the second readout data to the interface circuit comprises:
transmitting, by the serial-parallel conversion circuit, the second readout data to the interface circuit at a second transmission rate, wherein a ratio of the first transmission rate to the second transmission rate is N/M.
